(19) United States
(12) Patent Application Publication
(10) Pub. No.: US 2004/0147099 A1
(43) Pub. Date: Jul. 29, 2004

(54) Method of producing semiconductor device

(75) Inventors: Hiroshi Hashimoto, Kawasaki (JP); Kazuhiko Takada, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 10/756,403

(22) Filed: Jan. 14, 2004

(30) Foreign Application Priority Data
Jan. 23, 2003 (JP) 2003-014829

(51) Int. Cl. H01L 21/20

(52) U.S. Cl. 438/584

(57) ABSTRACT

A method for producing a semiconductor device is disclosed that is capable of improving device isolation capability of a device isolation film, and enables effective formation of gate insulating films having different film thicknesses. This method can be used in fabricating a semiconductor device having non-volatile memories with logic elements embedded. As one embodiment, a substrate protection film is formed on a silicon substrate, then an oxide film is formed in a flash cell region with a logic region being covered by the substrate protection film. Next, in the logic region, an intermediate oxide film is formed in a thick film region of the logic region with a thin film region of the logic region being covered by the substrate protection film. Then, the substrate protection film in the thin film region of the logic region is removed, and an oxide film is formed therein. At the same time, the oxide film already in the thick film region is oxidized again, and this results in a thicker oxide film in the thick film region.

### CROSS REFERENCE TO RELATED APPLICATIONS

This patent application is based on Japanese Priority Patent Application No. 2003-014829 filed on Jan. 23, 2003, the entire contents of which are hereby incorporated by reference.

### BACKGROUND OF THE INVENTION

1. Field of the Invention

The present invention relates to a method of producing a semiconductor device, more specifically, to a method capable of improving device isolation capability of a device isolation film, enabling effective formation of gate insulating films having different film thicknesses.

2. Description of the Related Art

Along with progress in integrated circuit technology, the technology of embedding semiconductor logic elements with semiconductor memory elements is attracting attention. For example, a semiconductor memory element, in particular, a non-volatile memory element, such as a flash memory, or an EPROM (Erasable Programmable Read Only Memory), or an EEPROM (Electrically Erasable Programmable Read-Only Memory), needs a low voltage MOS transistor working in read operations and a high voltage MOS transistor working in write and deletion operations.

For such a low voltage MOS transistor and a high voltage MOS transistor, it is necessary to form gate insulating films having different thicknesses. In the related art, for example, in Japanese Laid Open Application No. 2001-203285, and Japanese Laid Open Application No. 2002-349164, methods have been proposed for producing such a non-volatile memory and a low voltage MOS transistor and a high voltage MOS transistor having gate insulating films of different thicknesses.

Meanwhile, the so-called “STI (Shallow Trench Isolation)” technique is attracting attention as a device isolation technique for a higher integration degree.

Below, with reference to FIGS. 1A through 1C, FIGS. 2A through 2C, FIGS. 3A through 3C, and FIG. 4, an explanation is made of the method of the related art for forming gate insulating films having different film thicknesses by using the STI as the device isolation method. Here, the element region where the thicker gate insulating film is formed is indicated as “thick gate film region”, and the element region where the thinner gate insulating film is formed is indicated as “thin gate film region”.

In FIG. 1A, an oxide film 502 and a nitride film 503 are formed on the silicon substrate 501. Then, a resist mask 504 is formed to pattern the substrate in order to form trench grooves 505 according the STI method.

In FIG. 1B, the oxide film 502 and nitride film 503 are etched using the resist mask 504, and further, the substrate 501 is etched so that the STI trench grooves 505 are formed.

In FIG. 1C, a thermal oxide film is formed in the trench grooves 505, and then an oxide film 506 is formed to bury the trench grooves 505.

In FIG. 2A, the oxide film 506 is flattened by etch-back using CMP (Chemical and Mechanical Polishing).

In FIG. 2B, the oxide film 502 and nitride film 503 are removed, and the device isolation films 507 are formed.

In FIG. 2C, an oxide film 508 is formed by oxidation in both the thick gate film region and the thin gate film region.

In FIG. 3A, a resist mask 509 is formed to cover the thick gate film region, and the oxide film 508 in the thin gate film region is removed. At this time, depressions 510 are also formed.

In FIG. 3B, the resist mask 509 is removed, and the substrate is oxidized. As a result, a thin gate oxide film 511 is formed in the thin gate film region, and the oxide film 508 already formed in the thick gate film region is further oxidized, forming a thicker gate oxide film 512.

In FIG. 3C, gate electrodes 513 are formed in the thick gate film region and the thin gate film region.

In FIG. 4, a bulk interlayer film 514 is formed to cover the gate electrodes 513. On the interlayer film 514, a first interconnection layer 515 is formed, and an interlayer film 516 is formed to cover the first interconnection layer 515. On the interlayer film 516, a second interconnection layer 517 is formed, and a cover layer 518 is formed to cover the second interconnection layer 517.

As shown in FIG. 3A, when forming gate insulating films having different thicknesses, depressions 510 are formed on the device isolation film 507. The depressions 510 cause problems not only in formation of the device isolation film 507 in STI, but also in formation of device isolation films in LOCOS.

The reason for the formation of the depressions 510 is that, as shown in FIG. 3A, the oxide film 508 already formed in the thick gate film region has to be removed before formation of the thin gate insulating film 511.

The removal step involves wet etching using a fluoride solution. Because of the wet etching, the device isolation film 507 is also partially etched together with removal of the oxide film 508 by etching, removing a part of the device isolation film 507, which forms boundaries of different element regions.

Further, when forming a number of different insulating films, the etching step using the fluoride solution is usually repeated for a few times, therefore, a considerable portion of the device isolation film 507 is removed.

The amount of the removed portion of the device isolation film 507, that is, the size of the depressions 510, directly influences the reliability of the gate oxide film and the bump performance of the transistors, and further, influences the reliability of the overall logic circuit embedded memory device.

Therefore, it is desirable that gate insulating films having different thicknesses be formed without degradation of device isolation capability of the device isolation film.

### SUMMARY OF THE INVENTION

Accordingly, it is an object of the present invention to solve one or more of the problems of the related art.

It is a more specific object of the present invention to provide a method for producing a semiconductor device capable of improving the device isolation capability of a device isolation film, and effective formation of gate insulating films having different film thicknesses.

According to a first aspect of the present invention, there is provided a method for producing a semiconductor device including a number of elements having different functions and formed in a first region and a second region on a substrate. The method includes the steps of forming a device isolation film on the substrate by using a first mask pattern covering the first region and the second region, forming a first insulating film in the second region while covering the first region with a second mask pattern, and removing the second mask pattern from the first region and forming a second insulating film thicker than the first insulating film in the first region.

According to a second aspect of the present invention, there is provided a method for producing a semiconductor device including a plurality of elements having different functions formed in a first region and a second region on a substrate. The method includes the steps of forming a device isolation film on the substrate by using a first mask pattern covering the first region and the second region, forming a first insulating film in the second region while covering the first region with a second mask pattern, removing the second mask pattern from the first region and forming a second insulating film in a part of the first region while covering the first region except for the part of the first region with a third mask pattern, and removing the third mask pattern from the first region and forming a third insulating film in the part of the first region.

In the step of removing the third mask pattern, preferably, the third insulating film is formed while the second insulating film is oxidized again.

In the step of forming the device isolation film, the device isolation film may be formed by STI (Shallow Trench Isolation) method or by LOCOS (Local Oxidation of Silicon) method.

In the step of forming the device isolation film, preferably, the first mask pattern includes a nitride film, and the nitride film is removed by dry etching.

According to a third aspect of the present invention, there is provided a semiconductor device production method including the steps of forming a device isolation film on a substrate by using a first mask pattern covering a first region and a second region on the substrate, forming a first insulating film in the first region while covering the second region with a second mask pattern, and removing the second mask pattern and forming a second insulating film in the second region.

In the step of removing the second mask pattern, preferably, the second insulating film is formed while the first insulating film is oxidized again.

According to a fourth aspect of the present invention, there is provided a semiconductor device production method including the steps of forming a device isolation film on a substrate by using a first mask pattern covering a first region through an n-th region (n is an integer equal to or greater than two), forming an insulating film in the n-th region while covering the first region through the (n−1)-th region with a second mask pattern, then removing the second mask pattern and forming an insulating film in the (n−1)-th region while covering the regions other than the (n−1)-th region with a third mask-pattern.

The present invention may be used, for example, in embedding logic elements into non-volatile memory elements. According to the present invention, it is possible to avoid the step of removing the oxide film, which causes the depressions, when forming gate insulating films having different thicknesses. The objects of the present invention are achieved by combining existing processing techniques such as formation of resist mask patterns, oxidation, and removal of the resist mask patterns, and any specified film thickness difference between the gate insulating films can be achieved by repeating the above process combination for a certain number of times.

The present invention, however, is not limited to the technique of embedding logic elements into non-volatile memory elements, but is applicable to formation of gate insulating films having different thicknesses in any element regions separated by device isolation films.

The present invention is not limited by the number of element regions or the number of different gate film thicknesses of a semiconductor device.

In the present invention, when forming a number of gate insulating films having different thicknesses, the gate insulating films are formed by a single pre-oxidation process. Specifically, it is sufficient to merely etch the substrate protection film in element regions where the gate insulating films are formed; therefore, the depth of the depressions produced in each element region is limited to the depth value produced in a single pre-oxidation process.

According to the present invention, the original device isolation functions of the device isolation insulating films are maintained, and reliability of the overall semiconductor device can be obtained. Further, because gate insulating films having different film thicknesses can-be formed effectively, the semiconductor device obtained according to the present invention can be flexibly used in environments including power supplies or input/output systems having different voltages, and even in environments including combinations of power supplies and input/output systems.

These and other objects, features, and advantages of the present invention will become more apparent from the following detailed description of the preferred embodiments given with reference to the accompanying drawings.

### BRIEF DESCRIPTION OF THE DRAWINGS

FIGS. 1A through 1C are cross-sectional views showing the method of the related art for forming gate insulating films having different film thicknesses;

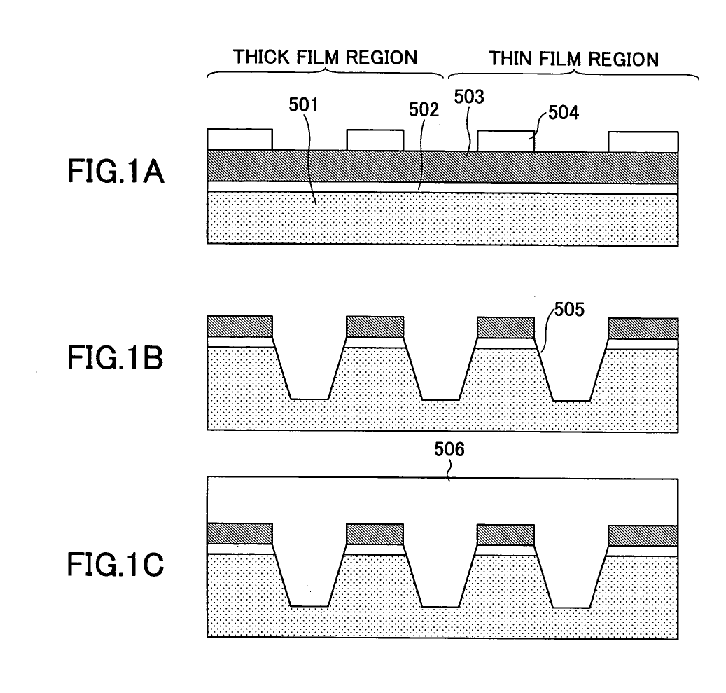

FIGS. 2A through 2C, continued from FIG. 1C, are cross-sectional views showing the method of the related art for forming the gate insulating films having different film thicknesses;

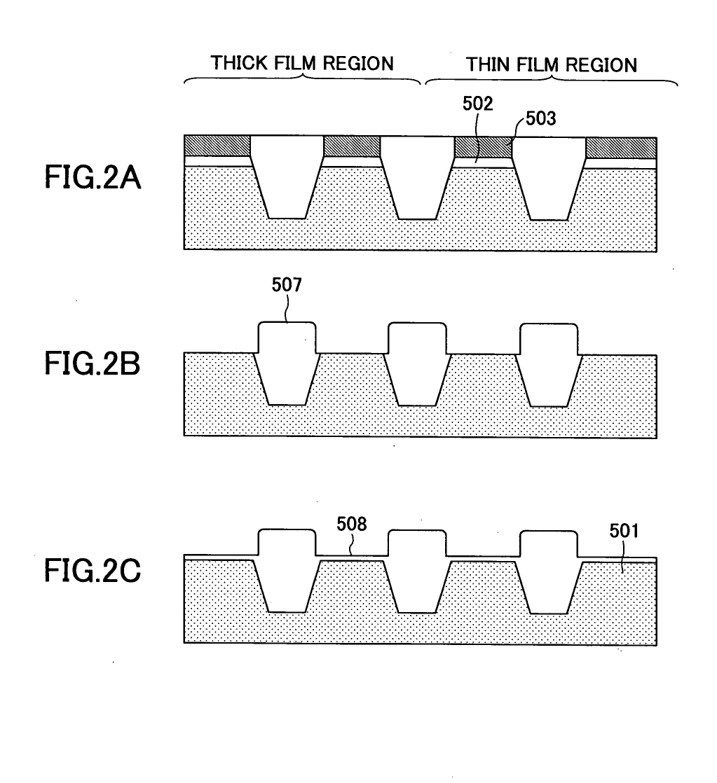

FIGS. 3A through 3C, continued from FIG. 2C, are cross-sectional views showing the method of the related art for forming gate insulating films having different film thicknesses;

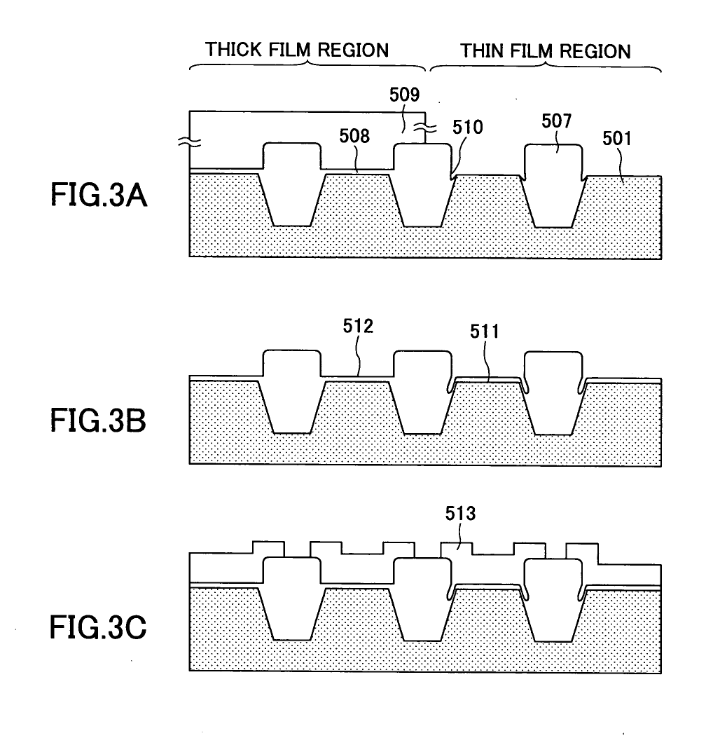

FIG. 4, continued from FIG. 3C, is a cross-sectional view showing the method of the related art for forming gate insulating films having different-film thicknesses;

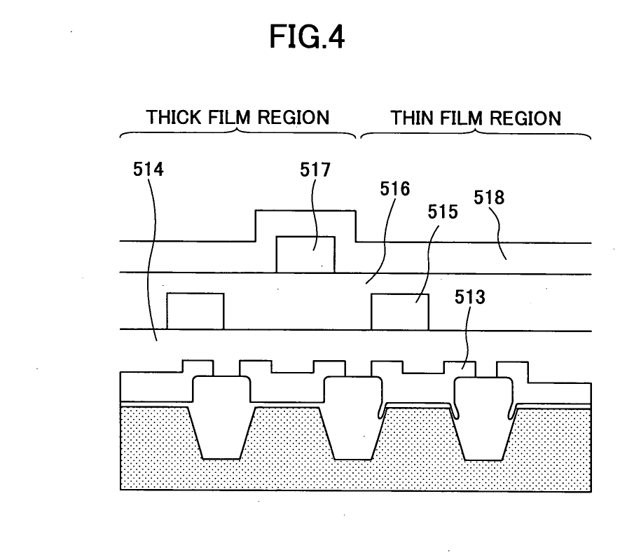

FIGS. 5A through 5C are cross-sectional views showing the method of the first embodiment of the present invention for forming a semiconductor device;

FIGS. 6A through 6C, continued from FIG. 5C, are cross-sectional views showing the semiconductor device production method of the first embodiment of the present invention;

FIGS. 7A through 7C, continued from FIG. 6C, are cross-sectional views showing the semiconductor device production method of the first embodiment of the present invention;

FIGS. 8A through 8C, continued from FIG. 7C, are cross-sectional views showing the semiconductor device production method of the first embodiment of the present invention;

FIGS. 9A through 9C, continued from FIG. 8C, are cross-sectional views showing the semiconductor device production method of the first embodiment of the present invention;

FIG. 10, continued from FIG. 9C, is a cross-sectional view showing the semiconductor device production method of the first embodiment of the present invention;

FIGS. 11A through 11C are cross-sectional views showing the method of the second embodiment of the present invention for forming a semiconductor device;

FIGS. 12A through 12C, continued from FIG. 1C, are cross-sectional views showing the semiconductor device production method of the second embodiment of the present invention;

FIGS. 13A through 13C, continued from FIG. 12C, are cross-sectional views showing the semiconductor device production method of the second embodiment of the present invention;

FIGS. 14A through 14C, continued from FIG. 13C, are cross-sectional views showing the semiconductor device production method of the second embodiment of the present invention;

FIGS. 15A through 15C, continued from FIG. 14C, are cross-sectional views showing the semiconductor device production method of the second embodiment of the present invention;

FIG. 16, continued from FIG. 15C, is a cross sectional-view showing the semiconductor device production method of the second embodiment of the present invention;

FIGS. 17A through 17C are cross-sectional views showing a method for producing a semiconductor device according to a third embodiment of the present invention;

FIGS. 18A through 18C, continued from FIG. 17C, are cross-sectional views showing the semiconductor device production method of the third embodiment of the present invention;

FIGS. 19A through 19C, continued from FIG. 18C, are cross-sectional views showing the semiconductor device production method of the third embodiment of the present invention;

FIGS. 20A and 20B, continued from FIG. 19C, are cross-sectional views showing the semiconductor device production method of the third embodiment of the present invention;

FIGS. 21A through 21E are cross-sectional views showing a method for producing a semiconductor device according to a fourth embodiment of the present invention; and

FIGS. 22A through 22E, continued from FIG. 21E, are cross-sectional views showing the semiconductor device production method of the fourth embodiment of the present invention;

### DESCRIPTION OF THE PREFERRED EMBODIMENTS

Below, preferred embodiments of the present invention are explained with reference to the accompanying drawings.

First Embodiment

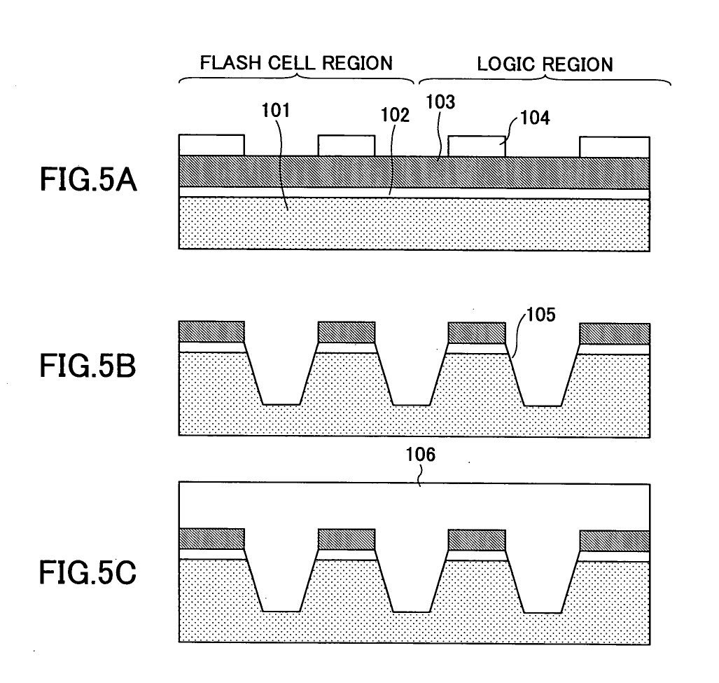

FIGS. 5A through 5C, FIGS. 6A through 6C, FIGS. 7A through 7C, FIGS. 8A through 8C, FIGS. 9A through 9C, and FIG. 10 are cross-sectional views showing the method of the first embodiment of the present invention for forming a semiconductor device.

In the present embodiment, for example, a logic element is embedded in a non-volatile memory such as a flash memory cell, the element region where the flash memory cell is formed is indicated as “flash cell region”, and the element region where the logic element is formed is indicated as “logic region”. The STI is used for device isolation.

In FIG. 5A, an oxide film 102 is formed on a silicon substrate 101, and then a nitride film 103 is formed on the oxide film 102. The oxide film 102 and the nitride film 103 act as substrate protection films when forming the device isolation film.

In the present embodiment, for example, the oxide film 102 is formed at 900 degrees C. to a thickness of 10 nm. The nitride film 103 is formed by CVD to 150 nm in thickness.

Then, a resist mask 104 is formed in order to pattern the substrate to form trench grooves 105 by means of STI.

In FIG. 5B, the oxide film 102 and the nitride film 103 are etched using the resist mask 104, further, the silicon substrate 101 is etched up to a depth of 350 nm. Thereby, STI trench grooves 105 are formed.

In this step, after the oxide film 102 and nitride film 103 are etched., the resist mask 104 may be removed, and the silicon substrate 101 may be etched using the nitride film 103 as a mask.

In FIG. 5C, in order to perform surface processing of the trench grooves 105, a thermal oxide film (not illustrated) is formed in the trench grooves 105. In the present embodiment, for example, the thermal oxide film is formed to be 10 nm in thickness by an oxidation process at 850 degrees C. Then an oxide film 106 is formed to bury the trench grooves 105. In the present embodiment, for example, the oxide film 106 is formed to 700 nm in thickness by CVD.

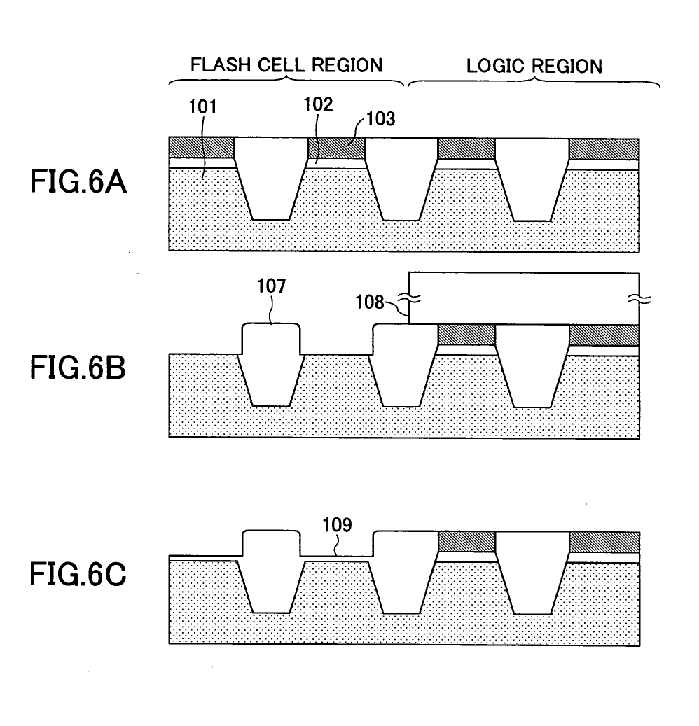

In FIG. 6A, the oxide film 106 is flattened by etch-back using CMP (Chemical and Mechanical Polishing).

In FIG. 6B, a resist mask 108 is formed to cover regions other than the flash cell region. Then, dry etching is performed using a mixing gas of CHF₃/O₂/Ar, and thereby the nitride film 103 in the flash cell region is removed. Further, wet etching is performed using a fluoride solution, and thereby the oxide film 102 in the flash cell region is removed. As a result, a device isolation film 107 is formed in the flash cell region. After that, the resist mask 108 is removed.

In FIG. 6C, a tunneling oxide film 109 is formed by oxidation in the flash cell region. The logic region is not oxidized since the nitride film 103 still exists in this region.

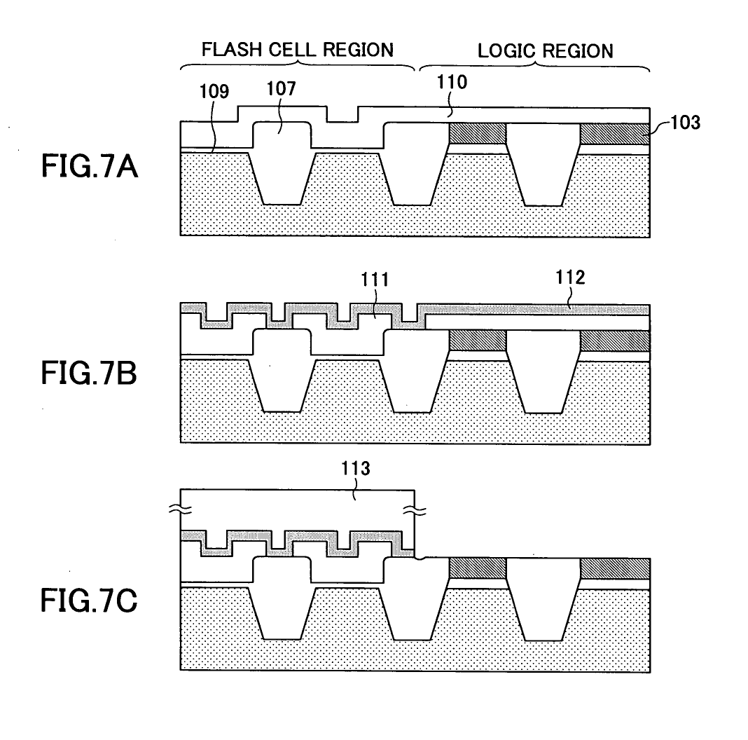

In FIG. 7A, a P-doped amorphous silicon film 110 is formed to cover the device isolation film 107 and the tunneling oxide film 109 in the flash cell region, and the nitride film 103 in the logic region. In the present embodiment, for example, the amorphous silicon film 110 is formed to be 100 nm in thickness.

In FIG. 7B, a planar resist mask (not illustrated) for a floating gate 111 of the flash memory is formed by patterning. Then, the amorphous silicon film 110 is etched to form the floating gate 111.

Next, an ONO film 112 is formed to cover the floating gate 111. In the present embodiment, for example, the ONO film 112 is formed by stacking in order (not illustrated) a 7 nm oxide film formed by CVD at 750 degrees C., a 9 nm silicon nitride film formed by CVD at 725 degrees C., and a 6 nm oxide film formed by thermal oxidation at 950 degrees C. in an atmosphere of O₂/H₂.

In FIG. 7C, a resist mask 113 is formed to cover the flash cell region. Next, the floating gate 111 and the ONO film 112 formed in the logic region are selectively removed by etching.

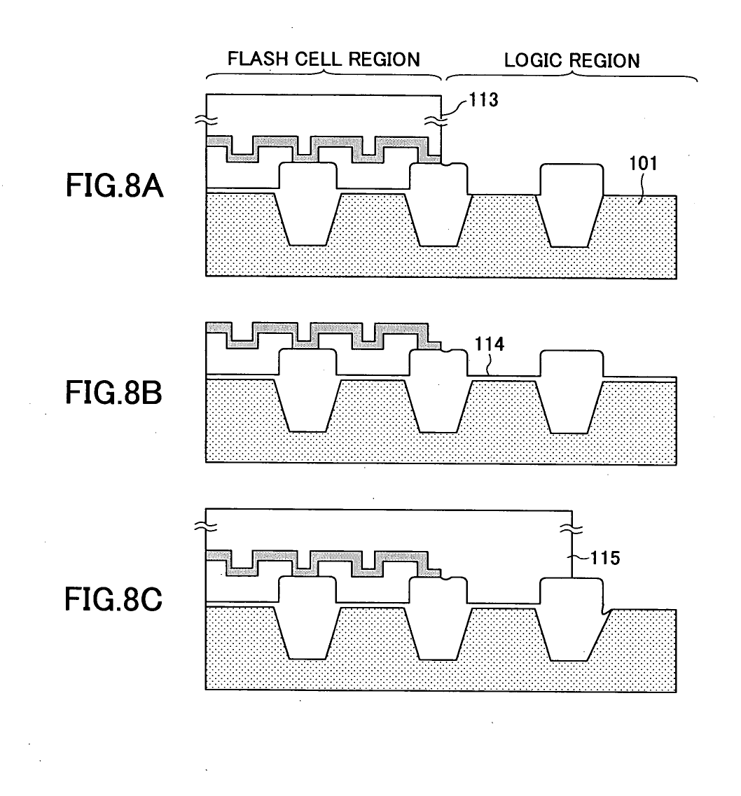

In FIG. 8A, the oxide film 102 and nitride film 103 in the logic region are selectively removed by using the resist mask 113. Specifically, dry etching is performed using a mixing gas of CHF₃/O₂/Ar, and thereby the nitride film 103 in the logic region is removed. Further, wet etching is performed using a fluoride solution, and thereby the oxide film 102 in the logic region is removed. After that, the resist mask 113 is removed.

In FIG. 8B, the silicon substrate 101 exposed in the logic region is oxidized, and thereby, a silicon dioxide film 114 is formed in the logic region.

In FIG. 8C, a resist mask 115 is formed to cover regions other than the thin gate film region. Then, using the resist mask 115, the oxide film 114 is selectively removed. After that, the resist mask 115 is removed.

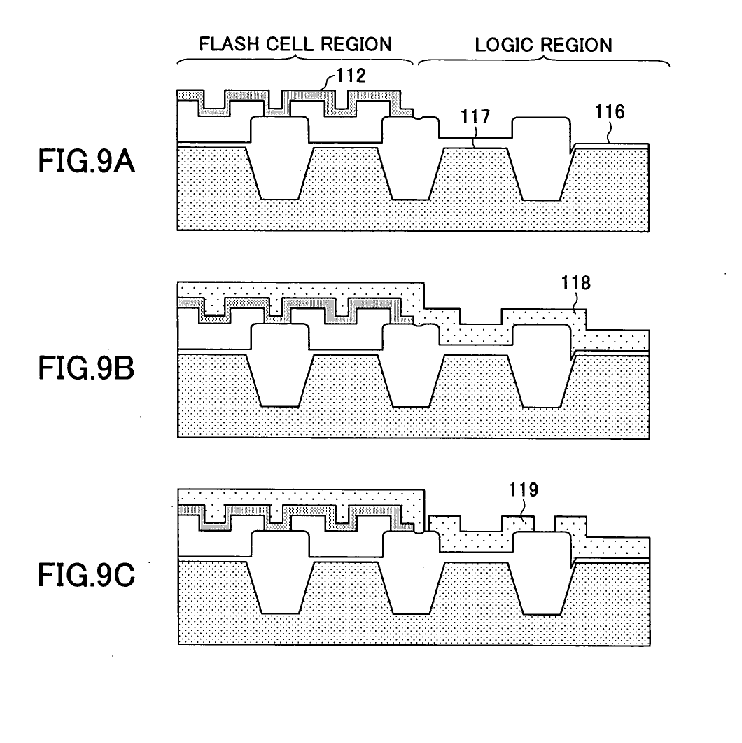

In FIG. 9A, the whole logic region is oxidized. As a result, a thin gate oxide film 116 is formed in the thin gate film region.

In the thick gate film region, the oxide film 114 already formed is further oxidized forming a thick gate oxide film 117. The flash cell region is not oxidized at this time since it is covered by the ONO film 112.

In FIG. 9B, a poly-silicon film 118 is formed in order to form a gate electrode 119. In the present embodiment, for example, the poly-silicon film 118 is formed by CVD to 180 nm in thickness. Further, in order to reduce the electrical resistance of the gate electrode 119, for example, P⁺ ions may be implanted into regions other than a P-channel region (not illustrated) at implanting energy of 20 keV with a concentration of 4×10¹⁵ cm⁻². In order to activate the implanted impurities, the substrate may be annealed in a nitrogen atmosphere for 10 seconds at 1000 degrees C. Further, a nitride film acting as a reflection resisting film may be formed by CVD to 29 nm in thickness.

In FIG. 9C, patterning is performed and the gate electrode 119 is formed. Here, in order to form offsets of transistors, BF²⁺ or B⁺ ions may be selectively implanted into a P-channel transistor (not illustrated) and P⁺ ions may be implanted into an N-channel transistor (not illustrated). Next, a sidewall spacer (not illustrated) may also be formed by depositing an oxide film to 100 nm in thickness by CVD. Alternatively, a nitride film may be formed by CVD.

In order to form source and drain regions, 2+BF or B+ions may be implanted into the P-channel region (not illustrated), and P+ or AS+ions may be implanted into the N-channel region (not illustrated). To activate these implanted impurities, the substrate may be annealed in a nitrogen atmosphere for 10 seconds at 1000 degrees C.

In order to form silicide on the gate electrode, in the source diffusion region and the drain diffusion region, the surface of the silicon substrate 101 may be processed by a fluoride solution, and cobalt and SALICIDE (self align silicide) may be formed thereon.

Further, in order to reduce the electrical resistances of the gate electrode, the source diffusion region and the drain diffusion region, for example, tungsten silicon (WSi) may be used for the gate electrode, and silicide may be used for the source diffusion region and the drain diffusion region.

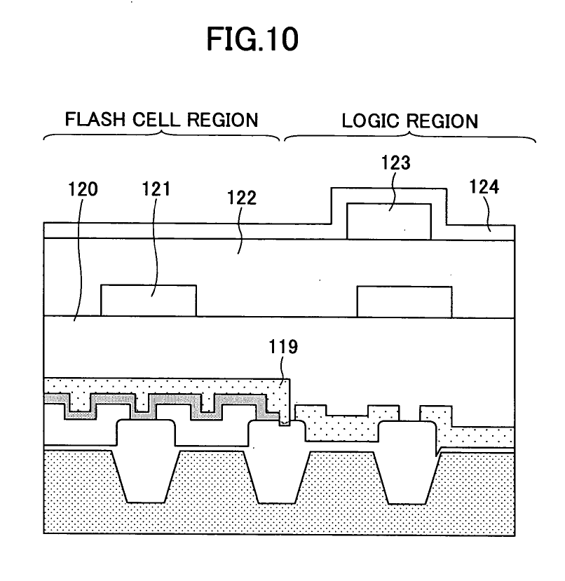

In FIG. 10, a bulk interlayer film 120 is formed to cover the gate electrodes 119. On the interlayer film 120, a first interconnection layer 121 is formed, and an interlayer film 122 is formed to cover the first interconnection layer 121. On the interlayer film 122, a second interconnection layer 123 is formed, and a cover layer 124 is formed to cover the second interconnection layer 123.

According to the semiconductor device production method of the present embodiment, the substrate protection films 102 and 103 formed for formation of the device isolation film 107 are also utilized in formation of the gate oxide films 116 and 117 having different thicknesses. Alternatively, for example, an oxidation step by masking may be included after the substrate protection films are removed partially or completely (referring to FIG. 6B and FIG. 6C).

As described above, in the semiconductor device production method of the present embodiment, elements having different functions are formed in a first region and a second region on the substrate 101. First, the substrate protection films 102 and 103 are formed to cover the first region where the logic element is to be formed and the second region where the non-volatile memory element is to be formed. Using the substrate protection films 102 and 103, the device isolation film 107 is formed on the substrate 101.

Next, a tunnel oxide film 109 is formed in the second region while the first region is covered with a resist mask 108. Next, the resist mask 108 is removed from the first region, and a gate oxide film 117 thicker than the tunnel oxide film is formed in the first region.

Second Embodiment

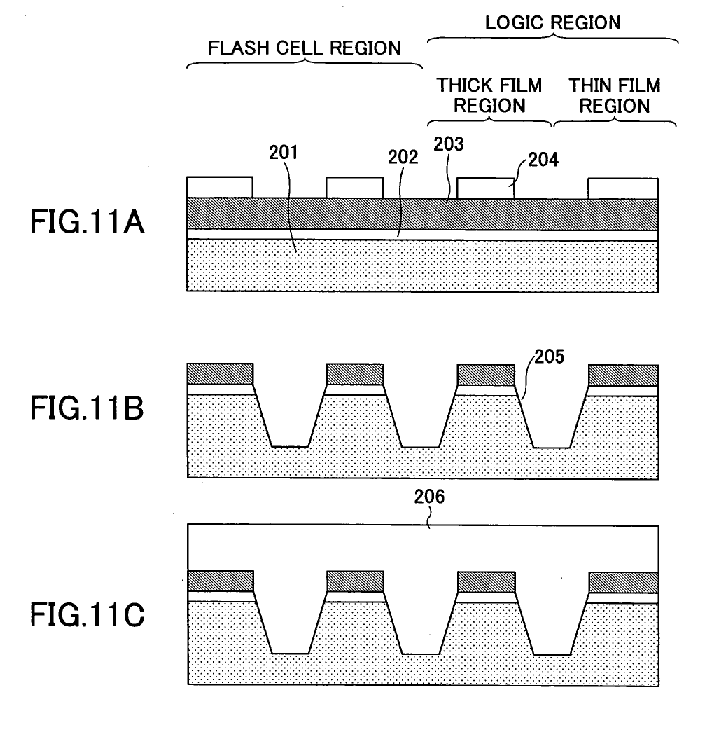

FIGS. 11A through 11C, FIGS. 12A through 12C, FIGS. 13A through 13C, FIGS. 14A through 14C, FIGS. 15A through 15C, and FIG. 16 are cross-sectional views showing the method of the second embodiment of the present invention for forming a semiconductor device.

In the present embodiment, the same as the first embodiment, a logic element is embedded in a non-volatile memory such as a flash memory cell; the element region where the flash memory cell is formed is indicated by “flash cell region”, and the element region where the logic element is formed is indicated by “logic region”. STI is used for device isolation. Further, in the logic region, the area where the thick gate insulating film is formed is indicated as “thick gate film region”, and the area where the thin gate insulating film is formed is indicated as “thin gate film region”.

In FIG. 11A, an oxide film 202 is formed on a silicon substrate 201, and then a nitride film 203 is formed on the oxide film 202. The oxide film. 202 and the nitride film 203 act as substrate protection films when forming the device isolation film.

In the present embodiment, for example, the oxide film 202 is formed at 900 degrees C. to a thickness of 10 nm. The nitride film 203 is formed by CVD to 150 nm in thickness.

Then, a resist mask 204 is formed in order to pattern the substrate to form trench grooves 205 by means of STI.

In FIG. 11B, the oxide film 202 and the nitride film 203 are etched using the resist mask 204; further, the silicon substrate 201 is also etched up to a depth of 350 nm. Thereby, STI trench grooves 205 are formed.

In this step, after the oxide film 202 and nitride film 203 are etched, the resist mask 204 may be removed, and the silicon substrate 201 may be etched using the nitride film 203 as a mask.

In FIG. 11C, in order for surface processing of the trench grooves 205, a thermal oxide film (not illustrated) is formed in the trench grooves 205. In the present embodiment, for example, the thermal oxide film is formed to be 10 nm in thickness by an oxidation process at 850 degrees-C. Then an oxide film 206 is formed to bury the trench grooves 205. In the present embodiment, for example, an oxide film 206 is formed to 700 nm in thickness by CVD.

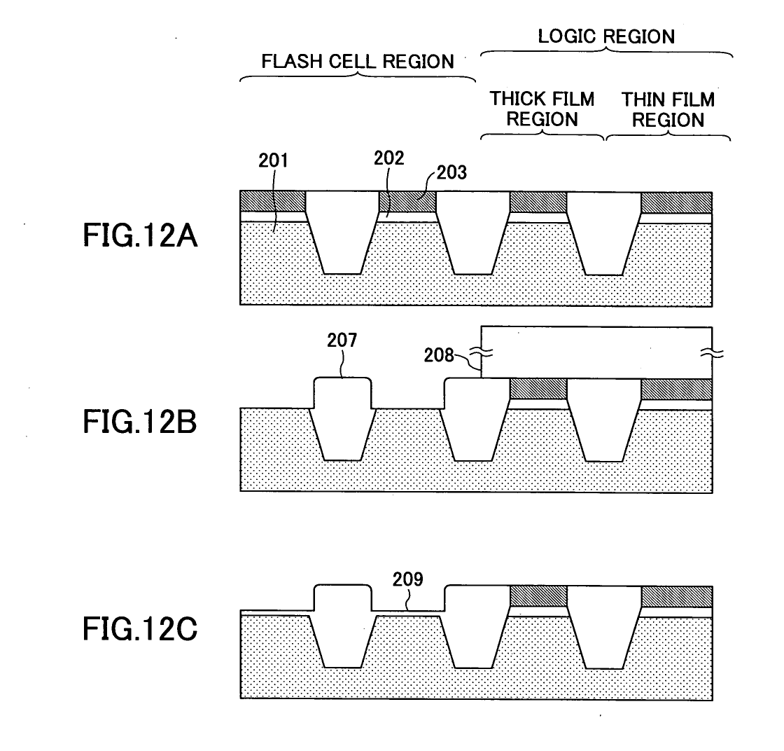

In FIG. 12A, the oxide film 206 is flattened by etch-back using CMP.

In FIG. 12B, a resist mask 208 is formed to cover regions other than the flash cell region. Then, dry etching is performed using a mixing gas of CHF₃/O₂/Ar, and thereby the nitride film 203 in the flash cell region is removed. Further, wet etching is performed using a fluoride solution, and thereby the oxide film 202 in the flash cell region is removed. As a result, a device isolation film 207 is formed in the flash cell region. After that, the resist mask 208 is removed.

In FIG. 12C, a tunneling oxide film 209 is formed by oxidation in the flash cell region. The logic region is not oxidized at this time since the nitride film 203 still exists in this region.

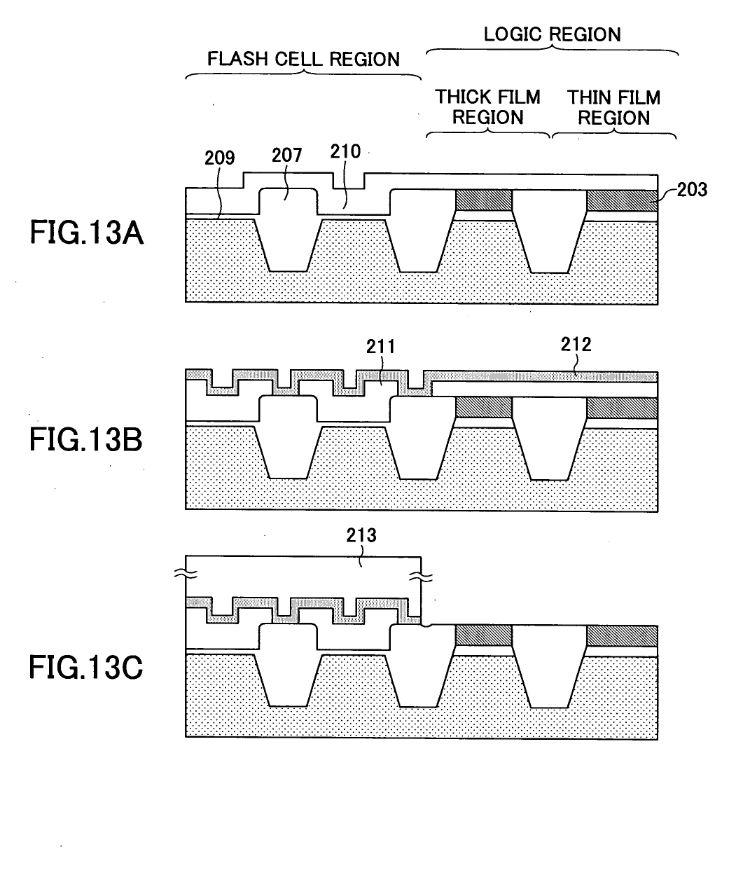

In FIG. 13A, a P-doped amorphous silicon film 210 is formed to cover the device isolation film 207 and the tunneling oxide film 209 in the flash cell region, and the nitride film 203 in the logic region. In the present embodiment, for example, the amorphous silicon film 210 is formed to be 100 nm in thickness.

In FIG. 13B, a planar resist mask (not illustrated) for a floating gate 211 of the flash memory is formed by patterning. Then, the amorphous silicon film 210 is etched to form the floating gate 211.

Next, an ONO film 212 is formed to cover the floating gate 211. In the present embodiment, for example, the ONO film 212 is formed by stacking in order (not illustrated) a 7 nm oxide film formed by CVD at 750 degrees C., a 9 nm silicon nitride film formed by CVD at 725 degrees C., and a 6 nm oxide film formed by thermal oxidation at 950 degrees C. in an atmosphere of O₂/H₂.

In FIG. 13C, a resist mask 213 is formed to cover the flash cell region. Next, the floating gate 211 and the ONO film 212 formed in the logic region are selectively removed by etching. After that, the resist mask 213 is removed.

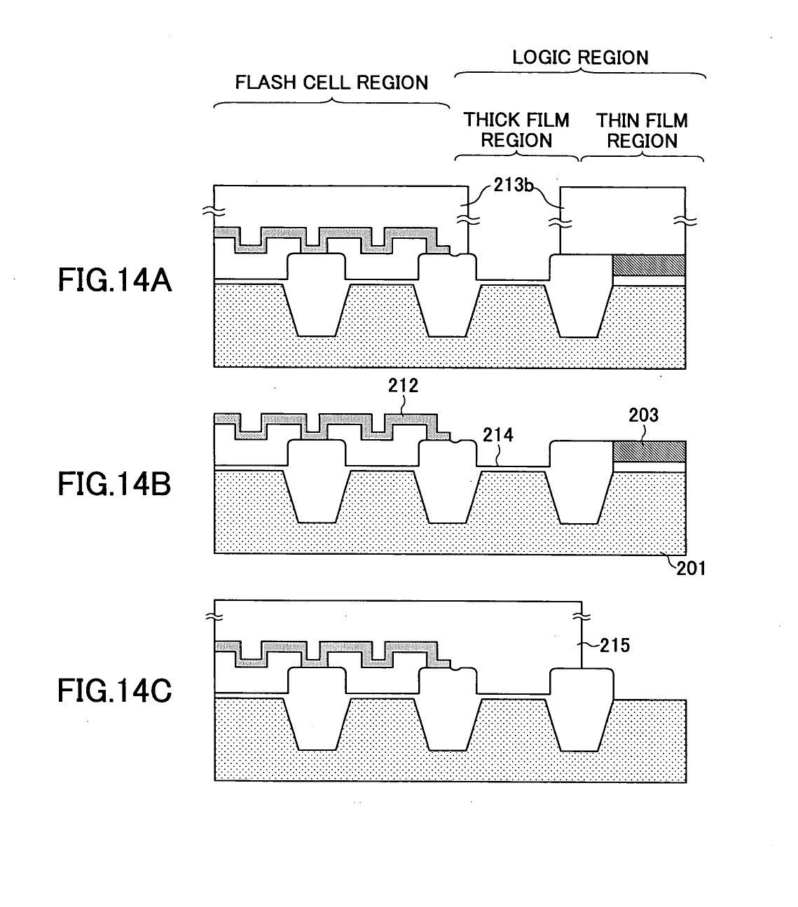

In FIG. 14A, a resist mask 213b is formed to cover regions other than the thick gate film region. Then using the resist mask 213b, the oxide film 202 and nitride film 203 in the thick gate film region of the logic region are selectively removed.

Specifically, dry etching is performed using a mixing gas of CHF₃/O₂/Ar, and thereby the nitride film 203 in the thick gate film region of the logic region is removed. Further, wet etching is performed using a fluoride solution, thereby the oxide film 202 in the thick gate film region of the logic region is removed. After that, the resist mask 213b is removed.

In FIG. 14B, the silicon substrate 201 exposed in the thick gate film region of the logic region is oxidized, and thereby, a silicon dioxide film 214 is formed in the thick gate film region of the logic region. The flash cell region and the thin gate film region of the logic region are not oxidized at this time since the former is covered by the ONO film 212 and the latter is covered by the nitride film 203.

In FIG. 14C, a resist mask 215 is formed to cover regions other than the thin gate film region. Then, using the resist mask 215, the oxide film 202 and nitride film 203 in the thin gate film region of the logic region are selectively removed. Specifically, dry etching is performed using a mixing gas of CHF₃/O₂/Ar, thereby the nitride film 203 in the thin gate film region of the logic region is removed. Further, wet etching is performed using a fluoride solution, thereby the oxide film 202 in the thin gate film region of the logic region is removed. After that, the resist mask 215 is removed.

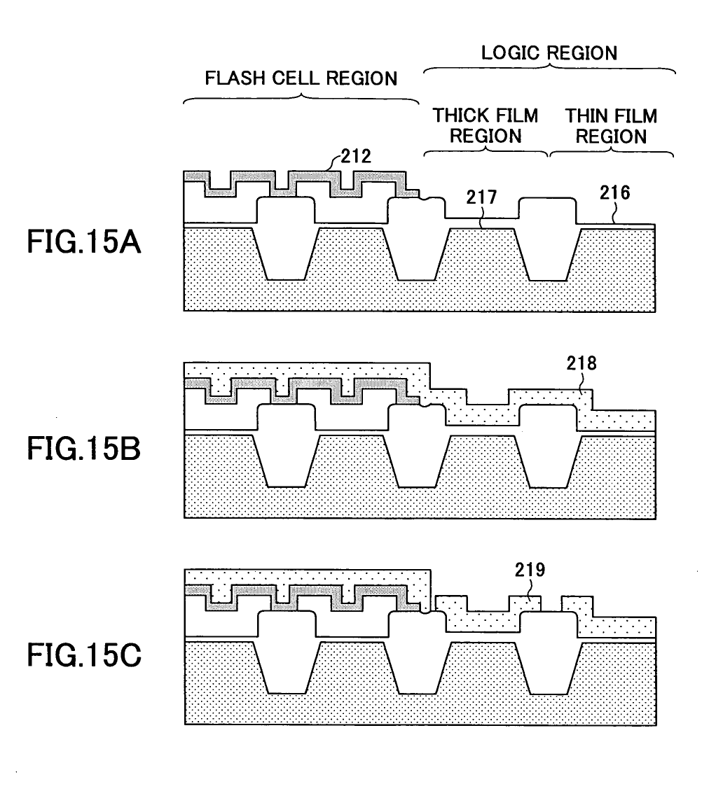

In FIG. 15A, the whole logic region is oxidized. As a result, a thin gate oxide film 216 is formed in the thin gate film region of the logic region. In the thick gate film region, the oxide film 214 already formed is further oxidized, forming a thick gate oxide film 217. The flash cell region is not oxidized at this time since it is covered by the ONO film 212.

In FIG. 15B, a poly-silicon film 218 is formed in order to form a gate electrode 219. In the present embodiment, for example, the poly-silicon film 218 is formed by CVD to 180 nm in thickness. Further, in order to reduce the electrical resistance of the gate electrode 219, for example, P⁺ ions may be implanted into regions other than a P-channel region (not illustrated) at implanting energy of 20 keV with a concentration of 4×10¹⁵ cm⁻². In order to activate the implanted impurities, the substrate may be annealed in a nitrogen atmosphere for 10 seconds at 1000 degrees C. Next, a nitride film acting as a reflection resisting film may be formed by CVD to 29 nm in thickness.

In FIG. 15C, patterning is performed and the gate electrode 219 is formed. Here, in order to form offsets of transistors, BF²⁺ or B⁺ ions may be selectively implanted into a P-channel transistor (not illustrated) and P+ions may be implanted into an N-channel transistor (not illustrated). Next, a sidewall spacer (not illustrated) may also be formed by depositing an oxide film to 100 nm in thickness by CVD. Alternatively, a nitride film may be formed by CVD.

In order to form source and drain regions, 2+BF or B+ions may be implanted into the P-channel region (not illustrated), and P+ or AS+ions may be implanted into the N-channel region (not illustrated). To activate these implanted impurities, the substrate may be annealed in a nitrogen atmosphere for 10 seconds at 1000 degrees C.

In order to form silicide on the gate electrode 219, in the source diffusion region and the drain diffusion region, the surface of the silicon substrate 201 may be processed by a fluoride solution, and cobalt and SALICIDE (self align silicide) may be formed thereon.

Further, in order to reduce the electrical resistances of the gate electrode 219, the source diffusion region and the drain diffusion region, for example, tungsten silicon (WSi) may be used for the gate electrode, and silicide may be used for the source diffusion region and the drain diffusion region.

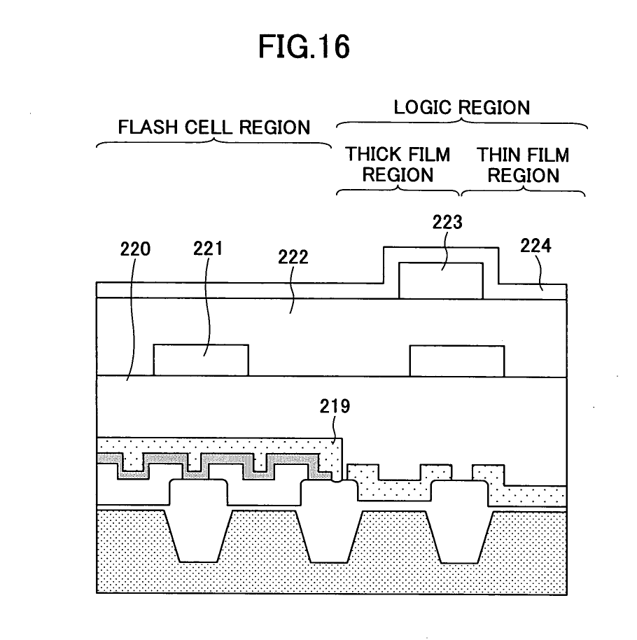

In FIG. 16, a bulk interlayer film 220 is formed to cover the gate electrode 219. On the interlayer film 220, a first interconnection layer 221 is formed, and an interlayer film 222 is formed to cover the first interconnection layer 221. On the interlayer film 222, a second interconnection layer 223 is formed, and a cover layer 224 is formed to cover the second interconnection layer 223.

According to the semiconductor device production method of the present embodiment, the substrate protection films 202 and 203 formed for formation of the device isolation film 207 are also utilized in formation of the gate oxide film 216 and 217 having different thicknesses. Alternatively, for example, an oxidation step by masking may be included after the substrate protection films are removed partially or completely (referring to FIG. 14A and FIG. 14B).

As described above, in the semiconductor device production method of the present embodiment, elements having different functions are formed in a first region and a second region on the substrate 201. First, the substrate protection films 202 and 203 are formed to cover the first region where the logic element is to be formed and the second region where the non-volatile memory element is to be formed. Using the substrate protection films 202 and 203, the device isolation film 207 is formed on the substrate 201.

Next, a tunnel oxide film 209 is formed in the second region while the first region is covered with a resist mask 208. Next, the resist mask 208 is removed from the first region, and a part of the first region is covered by a resist mask 213b, then an oxide film 214 is formed in the region of the first region other than that covered by the resist mask 213b. After that, the resist mask 213b is removed, and a thin gate oxide film 216 is formed in the part of the first region. To optimize the fabrication process, preferably, the step of forming the thin gate oxide film 216 is performed at the same time as the step of further oxidizing the oxide film 214 to form a thick gate oxide film 217.

Third Embodiment

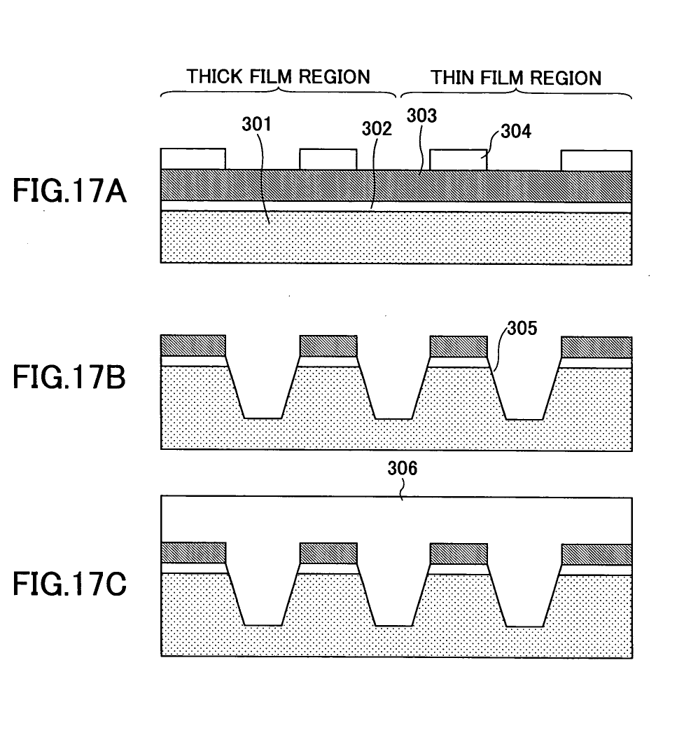

FIGS. 17A through 17C, FIGS. 18A through 18C, FIGS. 19A through 19C, and FIG. 20 are cross-sectional views showing the method of the third embodiment of the present invention for forming a semiconductor device.

In the present embodiment, the same as the second embodiment, the area where a thick gate insulating film is formed is indicated as “thick gate film region”, and the area where a thin gate insulating film is formed is indicated as “thin gate film region”, and the STI technique is used for device isolation.

In FIG. 17A, an oxide film 302 is formed on a silicon substrate 301, and then a nitride film 303 is formed on the oxide film 302. The oxide film 302 and the nitride film 303 act as substrate protection films when forming the device isolation film.

In the present embodiment, for example, the oxide film 302 is formed at 900 degrees C. to a thickness of 10 nm. The nitride film 303 is formed by CVD to 150 nm in thickness.

Then, a resist mask 304 is formed in order to pattern the substrate to form trench grooves 305 by means of STI.

In FIG. 17B, the oxide film 302 and the nitride film 303 are etched using the resist mask 304; further, the silicon substrate 301 is also etched up to a depth of 350 nm. Thereby, STI trench grooves 305 are formed.

In this step, after the oxide film 302 and nitride film 303 are etched, the resist mask 304 may be removed, and the silicon substrate 301 may be etched using the nitride film 303 as a mask.

In FIG. 17C, in order to perform surface processing of the trench grooves 305, a thermal oxide film (not illustrated) is formed in the trench grooves 305. In the present embodiment, for example, the thermal oxide film is formed to be 10 nm in thickness by an oxidation process at 850 degrees C. Then an oxide film 306 is formed to bury the trench grooves 305. In the present embodiment, for example, an oxide film 306 is formed to 700 nm in thickness by CVD.

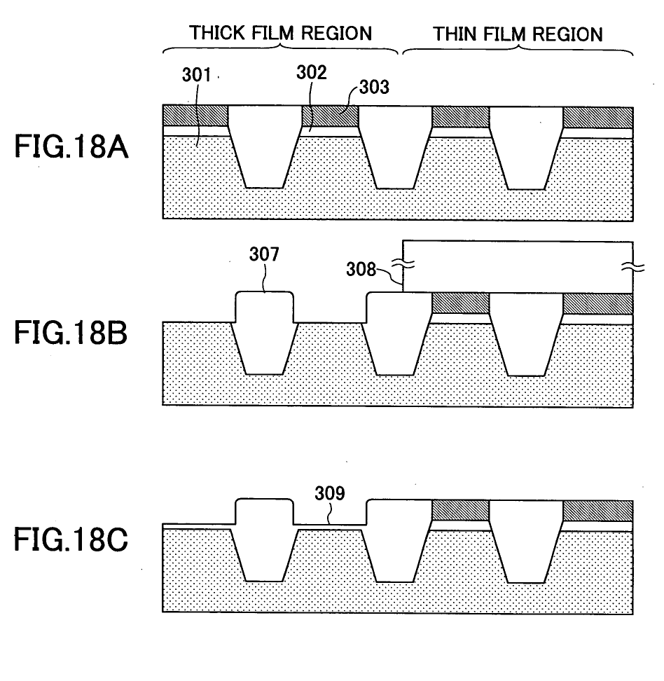

In FIG. 18A, the oxide film 306 is flattened by etch-back using CMP.

In FIG. 18B, a resist mask 308 is formed to cover regions other than the thick gate film region. Then, dry etching is performed using a mixing gas of CHF₃/O₂/Ar, and thereby the nitride film 303 in the flash cell region is removed. Further, wet etching is performed using a fluoride solution, and thereby the oxide film 302 in the thick gate film region is removed. As a result, a device isolation film 307 is formed in the thick gate film region. The oxide film 302 in the thin gate film region is not removed because the thin gate film region is covered by the nitride film 303. After that, the resist mask 308 is removed.

In FIG. 18C, an oxide film 309 is formed by oxidation in the thick gate film region.

In the present embodiment, for example, the oxide film 309 is formed to 6.5 nm in thickness in an oxygen atmosphere at 800 degrees C. The thin gate film region logic is not oxidized at this time since the nitride film 303 exists in this region.

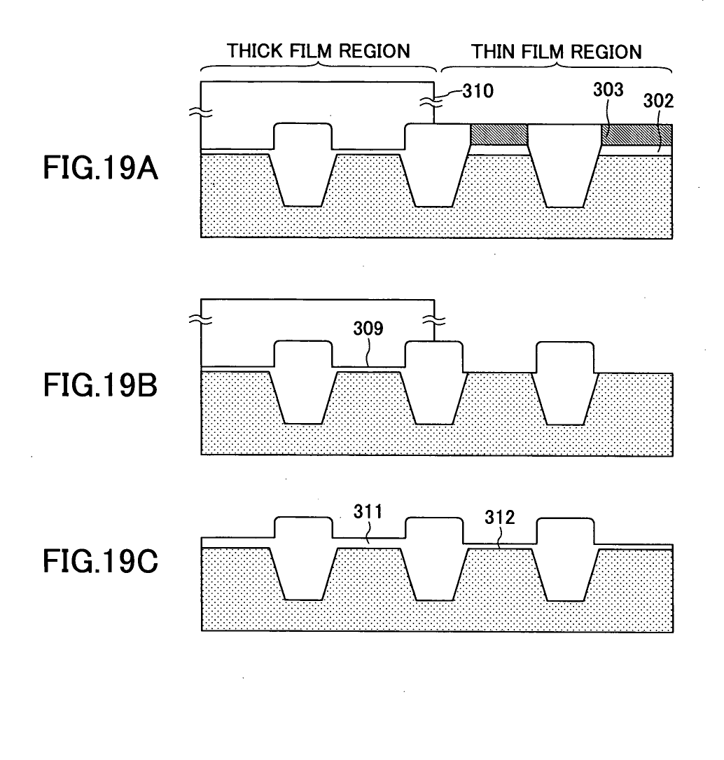

In FIG. 19A, a resist mask 310 is formed to cover the thick gate film region.

In FIG. 19B, the oxide film 302 and nitride film 303 in the thin gate film region are selectively removed. Specifically, dry etching is performed using a mixing gas of CHF₃/O₂/Ar, and thereby the nitride film 303 in the thin gate film region is removed. Further, wet etching is performed using a fluoride solution, thereby the oxide film 302 in the thin gate film region is removed. After that, the resist mask 310 is removed.

In FIG. 19C, to form the gate electrode 315, a gate oxide film 312 is formed in the thin gate film region in an oxidation atmosphere at 750 degrees. C. At the same time, the oxide film 309 already formed in the thick gate film region is further oxidized, forming a thick gate oxide film 311. In the present embodiment, for example, the gate oxide film 312 is formed to 3 nm in an oxidation atmosphere at 750 degrees C., and the thick gate oxide film 311 is formed to 8 nm.

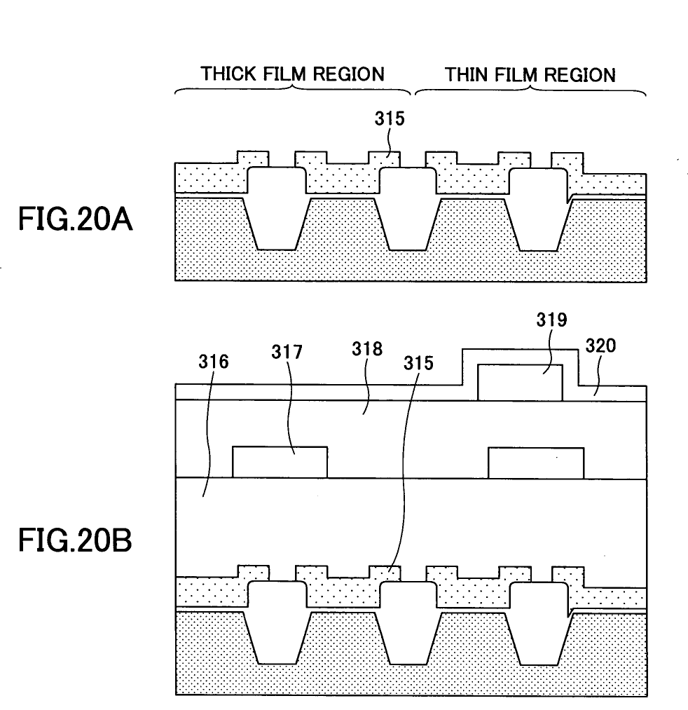

In FIG. 20A, a poly-silicon film (not illustrated) is formed in order to form a gate electrode 315. In the present embodiment, for example, the poly-silicon film is formed by CVD to 180 nm in thickness. Further, in order to reduce the electrical resistance of the gate electrode 315, for example, P⁺ ions may be implanted into regions other than a P-channel region (not illustrated) at implanting energy of 20 keV with a concentration of 4×10¹⁵ cm⁻². In order to activate the implanted impurities, the substrate may be annealed in a nitrogen atmosphere for 10 seconds at 1000 degrees C. Next, a nitride film acting as a reflection resisting film may be formed by CVD to 29 nm in thickness.

Next, though not illustrated, patterning is performed and the gate electrode 315 is formed. Here, in order to form offsets of transistors, BF²⁺ or B⁺ ions may be selectively implanted into a P-channel transistor (not illustrated) and P⁺ ions may be implanted into an N-channel transistor (not illustrated). Next, a sidewall spacer (not illustrated) may also be formed by depositing an oxide film to 100 nm in thickness by CVD. Alternatively, a nitride film may be formed by CVD.

In order to form source diffusion region- and drain diffusion region, BF²⁺ or B⁺ ions may be implanted into the P-channel region (not illustrated), and P⁺ or AS⁺ ions may be implanted into the N-channel region (not illustrated). To activate these implanted impurities, the substrate may be annealed in a nitrogen atmosphere for 10 seconds at 1000 degrees C.

In order to form silicide on the gate electrode, in the source diffusion region and the drain diffusion region, the surface of the silicon substrate 301 may be processed by a fluoride solution, and cobalt and SALICIDE (self align silicide) may be formed thereon.

Further, in order to reduce the electrical resistances of the gate electrode, the source diffusion region and the drain diffusion region, for example, tungsten silicon (WSi) may be used for the gate electrode, and silicide may be used for the source diffusion region and the drain diffusion region.

In FIG. 20B, a bulk interlayer film 316 is formed to cover the gate electrodes 315. On the interlayer film 316, a first interconnection layer 317 is formed, and an interlayer film 318 is formed to cover the first interconnection layer 317. On the interlayer film 318, a second interconnection layer 319 is formed, and a cover layer 320 is formed to cover the second interconnection layer 319.

According to the semiconductor device production method of the present embodiment, the substrate protection films 302 and 303 formed for formation of the device isolation film 307 are also utilized in formation of the gate oxide films 311 and 312 having different thicknesses. Alternatively, for example, an oxidation step by masking may be included after the substrate protection films are removed partially or completely (referring to FIG. 18B and FIG. 18C).

As described above, in the semiconductor device production method of the present embodiment, first, the substrate protection films 302 and 303 are formed to cover a first region and a second region, and using the substrate protection films 302 and 303, the device isolation film 307 is formed on the substrate 301.

Next, an oxide film 309 is formed in the first region while the second region is covered by a resist mask 308. Further, the resist mask 308 is removed, and a thin gate oxide film 312 is formed in the second region. To optimize the fabrication process, preferably, the step of forming the thin gate oxide film 312 is performed at the same time as the step of further oxidizing the oxide film 309 to form a thick gate oxide film 311.

Fourth Embodiment

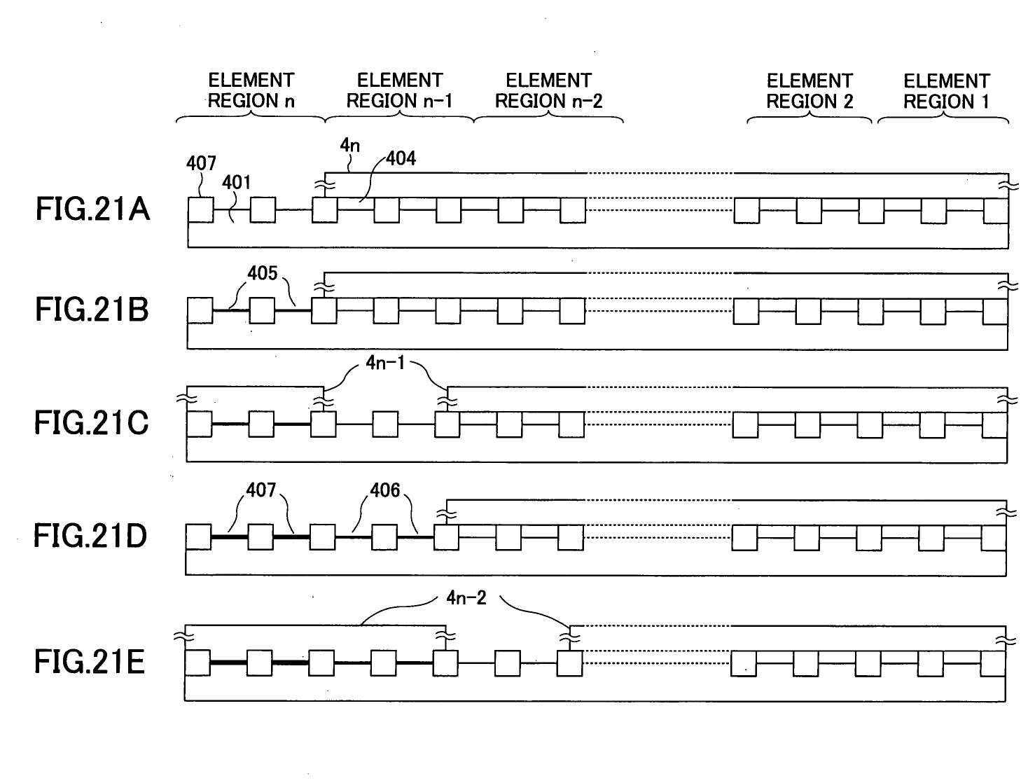

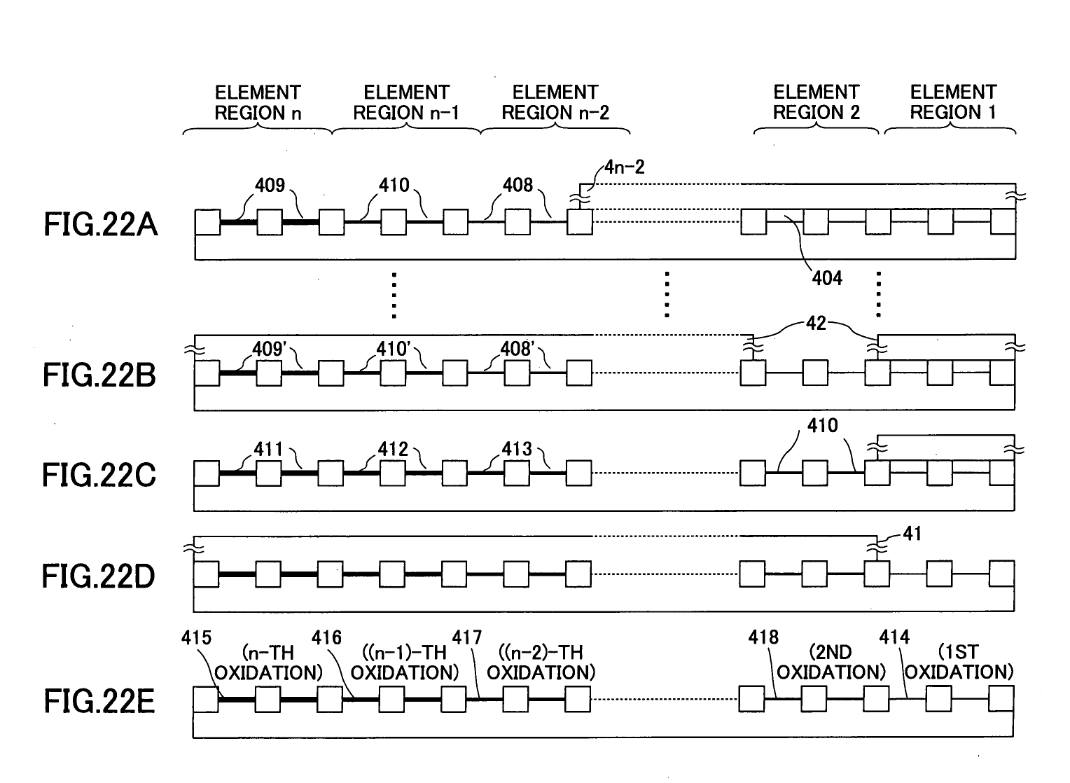

FIGS. 21A through 21E and FIGS. 22A through 22E are cross-sectional views showing the method of the fourth embodiment of the present invention for forming a semiconductor device.

The method disclosed in the present embodiment is a generalization of that of the third embodiment, and is for forming a number of gate oxide films having different thicknesses.

In FIGS. 21A through 21E and FIGS. 22A through 22E, element region n, element region n−1, element region 1 are indicated (n is an integer greater than 2). In the following description, it is assumed that gate oxide films having thicknesses in descending order are to be formed in these element regions. Specifically, the thickest gate oxide film is formed in the element region n, and the thinnest gate oxide film is formed in the element region 1. Further, in the following description, it is assumed that the fabrication steps up to those shown in FIG. 18A in the third embodiment have been completed, that is, the substrate protection film 404 (including a nitride film and an oxide film) is formed on the silicon substrate 401, and device isolation films 407 are formed to separate the element region n, the element region n−1, . . . , and the element region 1.

In FIG. 21A, a resist mask 4n is formed to cover regions other than the element region n. Then, the substrate protection film 404 in the element region n is removed. The same as in the third embodiment, the nitride film is removed by dry etching using a mixing gas of CHF₃/O₂/Ar, and the oxide film is removed by wet etching using a fluoride solution.

In FIG. 21B, the element region n is oxidized (the first time), and an oxide film 405 is formed in the element region n. Then, the resist mask 4n is removed.

In FIG. 21C, a resist mask 4n−1 is formed to cover regions other than the element region n−1. Then, the substrate protection film 404 in the element region n−1 is removed in the same way as described in FIG. 21A.

In FIG. 21D, first, the portion of the resist mask 4n−1 covering the element region n is removed. Then, the element region n and the element region n−1 are oxidized, and an oxide film 406 is formed in the element region n−1. By this oxidation process, the oxide film 405 already formed in the element region n is oxidized again (the second time), and forms an oxide film 407. Then, the resist mask 4n−1 is removed.

In FIG. 21E, a resist mask 4n−2 is formed to cover regions other than the element region n−2. Then, the substrate protection film 404 in the element region n−2 is removed in the same way as described in FIG. 21A.

In FIG. 22A, first, the portion of the resist mask 4n−2 covering the element region n and element region n−1 is removed. Then, the element regions n, n−1, and n−2 are oxidized, and an oxide film 408 is formed in the element region n−2. Due to this oxidation process, the oxide film 407 already formed in the element region n is oxidized again (the third time), thus forming an oxide film 409; the oxide film 406 already formed in the element region n−1 is oxidized again (the second time), thus forming an oxide film 410. Then, the resist mask 4n−2 is removed.

In this way, the same procedure is repeated, and it is assumed that prior to the step in FIG. 22B the oxidization step has been performed n−2 times in the element region n, forming an oxide film 409b, and one time in the not-illustrated element region 3, forming a new oxide film (not illustrated).

Explanations of the intermediate steps are omitted.

In FIG. 22B, a resist mask 42 is formed to cover regions other than the element region 2. Then, the substrate protection film 404 in the element region 2 is removed in the same way as described in FIG. 21A.

In FIG. 22C, the portion of the resist mask 42 covering the element regions n, n−1, . . . , 3 is removed. Then, the element regions n, n−1, . . . , 3 are oxidized, and an oxide film 410 is formed in the element region 2. Due to this oxidation process, the oxide film 409b already formed in the element region n is oxidized again (n−1 times), forming an oxide film 411; the oxide film 410b already formed in the element region n−1 is oxidized again (n−2 times)., forming an oxide film 412; and the oxide film 408b already formed in the element region n−2 is oxidized again (n−3 times), forming an oxide film 413. Then, the resist mask 42 is removed.

In FIG. 22D, a resist mask 41 is formed to cover regions other than the element region 1. Then, the substrate protection film 404 in the element region 1 is removed in the same way as described in FIG. 21A.

In FIG. 22E, the portion of the resist mask 41 covering the element regions n, n−1, . . . , 2 is removed. Then, the element regions n, n−1, . . . , 2 are oxidized, and an oxide film 414 is formed in the element region 1, having a thickness corresponding to one time oxidation.

Due to this oxidation process, the oxide film 411 already formed in the element region n is oxidized again (n times), forming an oxide film 415 with its thickness accumulated in n times of oxidation. Similarly, the oxide film 412, 413, . . . , 410 already formed in the element region n−1, n−2, . . . , 2 are oxidized again, forming oxide films 416, 417, . . . , 418. The thickness of the oxide films 416, 417, . . . , 418 corresponds to that accumulated in n−1, n−2, . . . , 2 times of oxidation.

According to the semiconductor device production method of the present embodiment, the substrate protection film 404 formed for formation of the device isolation films 407 is also utilized in formation of the gate oxide film 415, 416, and so on, having different thicknesses. Alternatively, for example, an oxidation step by masking may be included after the substrate protection film 404 is removed partially or completely (referring to FIG. 21A and FIG. 21B).

As described above, in the semiconductor device production method of the present embodiment, first, the substrate protection film 404 is formed to cover a first region through an n-th region (n is an integer greater than 2), and using the substrate protection film 404, the device isolation film 407 is formed on the substrate 401.

Next, an oxide film 405 is formed in the n-th region while the other regions are covered by a resist mask 4n. Further, the resist mask 4n is removed, and an oxide film 406 is formed in the (n−1)-th region while the regions other than the n-th region and the (n−1)-th region are covered by a resist mask 4n−1.

Specifically, after the resist mask 4n is removed, the substrate protection film 404 covering the (n−1)-th region is removed. Next, the regions following the (n−1)-th region are covered by the resist mask 4n−1, and the oxide film 406 is formed. Here, the regions following the (n−1)-th region means the regions having thickness less than that in the (n−1)-th region.

To optimize the fabrication process, preferably, the step of forming the oxide film 406 in the (n−1)-th region is performed at the same time as the step of further oxidizing the oxide film 405 in the n-th region to form a thicker oxide film 407. Due to this, among a number of element regions, the first oxidation processing is performed in each element region sequentially according to thickness of the oxide film to be formed therein, and the step of n times oxidation in the n-th region is performed at the same time as the step of n−1 times oxidation in the (n−1)-th region. As a result, the steps of forming oxide films in different regions are completed at the same time (referring to FIG. 22E), and the gate oxide film 415 formed in the element region n is thicker than the gate oxide film 416 formed in the element region n−1 by an amount corresponding to one oxidation process.

While the invention is described above with reference to specific embodiments chosen for purpose of illustration, it should be apparent that the invention is not limited to these embodiments, but numerous modifications could be made thereto by those skilled in the art without departing from the basic concept and scope of the invention.

For example, in the above, only the formation of gate insulating films having different thicknesses is described; therefore, any modification could be made to the process subsequent to the formation of the electrode formation, that is, the process subsequent to that in FIG. 9B, or FIG. 15B, or FIG. 20A.

In addition, in the above embodiments, the STI technique is used for device isolation, but the present invention is not limited to STI method; the LOCOS method, or other device isolation techniques can be used as long as they use oxide films or nitride films formed on a silicon substrate to separate element regions each formed with a MOS transistor.

Summarizing the effect of the invention, according to the present invention, it is possible to improve device isolation capability of a device isolation film, and effectively form gate insulating films having different film thicknesses.

Specifically, it is possible to suppress depressions formed in the device isolation insulating film, prevent degradation of performance of transistors., and maintain reliability of a semiconductor device:

In addition, it is possible to form gate insulating films having different thicknesses following a generalized procedure; therefore, it is possible to obtain semiconductor devices able to be used flexibly in environments including power supplies or input/output systems having different voltages, or even in environments including combinations of power supplies and input/output systems.

What is claimed is:

1. A method for producing a semiconductor device including a plurality of elements having different functions formed in a first region and a second region on a substrate, comprising the steps of:
forming a device isolation film on the substrate by using a first mask pattern covering the first region and the second region;
forming a first insulating film in the second region while covering the first region with a second mask pattern; and
removing the second mask pattern from the first region and forming a second insulating film thicker than the first insulating film in the first region.

2. A method for producing a semiconductor device including a plurality of elements having different functions formed in a first region and a second region on a substrate, comprising the steps of:
forming a device isolation film on the substrate by using a first mask pattern covering the first region and the second region;
forming a first insulating film in the second region while covering the first region with a second mask pattern removing the second mask pattern from the first region, and forming a second insulating film in a part of the first region while covering the first region except for the part of the first region with a third mask pattern; and
removing the third mask pattern from the first region and forming a third insulating film in the part of the first region.

3. The method as claimed in claim 2, wherein in the step of removing the third mask pattern, the third insulating film is formed while the second insulating film is oxidized again.

4. The method as claimed in claim 2, wherein in the step of forming the device isolation film, the device isolation film is formed by STI (Shallow Trench Isolation) method.

5. The method as claimed in claim 2, wherein in the step of forming the device isolation film, the device isolation film is formed by LOCOS (Local Oxidation of Silicon) method.

6. The method as claimed in claim 2, wherein in the step of forming the device isolation film, the first mask pattern includes a nitride film.

7. The method as claimed in claim 6, wherein in the step of forming the device isolation film, the nitride film is removed by dry etching.

8. A semiconductor device production method, comprising the steps of:
forming a device isolation film on a substrate by using a first mask pattern covering a first region and a second region on the substrate;
forming a first insulating film in the first region while covering the second region with a second mask pattern; and
removing the second mask pattern and forming a second insulating film in the second region.

9. The semiconductor device production method as claimed in claim 8, wherein in the step of removing the second mask pattern, the second insulating film is formed while the first insulating film is oxidized again.

10. A semiconductor device production method, comprising the steps of:
forming a device isolation film on a substrate by using a first mask pattern covering a first region through an n-th region (n is an integer equal to or greater than two);
forming an insulating film in the n-th region while covering the first region through the (n−1)-th region with a second mask pattern; and
removing the second mask pattern, and forming an insulating film in the (n−1)-th region while covering the regions other than the (n−1)-th region with a third mask pattern.

11. The semiconductor device production method as claimed in claim 10, wherein in the step of removing the second mask pattern., the insulating film in the (n−1)-th region is formed while the insulating film formed in the n-th region is being oxidized again.

12. The semiconductor device production method as claimed in claim 10, wherein in the step of forming the device isolation film, the device isolation film is formed by STI-(Shallow Trench Isolation) method.

13. The semiconductor device production method as claimed in claim 10, wherein in the step of forming the device isolation film, the device isolation film is formed by LOCOS (Local Oxidation of Silicon) method.

14. The semiconductor device production method as claimed in claim 10, wherein in the step of forming the device isolation film, a patterning step for forming the first mask pattern on the substrate and an etching step for forming a trench groove for the device isolation film are performed simultaneously.

15. The semiconductor device production method as claimed in claim 10, wherein in the step of forming the device isolation film, the first mask pattern includes a nitride film.

16. The semiconductor device production method as claimed in claim 15, wherein in the step of forming the device isolation film, the nitride film is removed by dry etching.
